(19) United States
(12) Patent Application Publication
(10) Pub. No.: US 2025/0234540 A1
(43) Pub. Date: Jul. 17, 2025

(54) SEMICONDUCTOR DEVICE WITH SIDEWALL OXIDIZED DIELECTRIC

(71) Applicant: NANYA TECHNOLOGY CORPORATION, NEW TAIPEI CITY (TW)

(72) Inventor: TE-YIN CHEN, TAOYUAN CITY (TW)

(21) Appl. No.: 19/055,785

(22) Filed: Feb. 18, 2025

Related U.S. Application Data
(63) Continuation-in-part of application No. 18/409,990, filed on Jan. 11, 2024.

(51) Int. Cl. H10B 41/35; H10B 41/10

(52) U.S. Cl. CPC H10B 41/35; H10B 41/10

(57) ABSTRACT

The present application discloses a semiconductor device having a sidewall oxidized dielectric and a method for fabricating the same. The semiconductor device includes a substrate; a tunnel insulating layer disposed over the substrate; a floating gate disposed over the tunnel insulating layer; a laterally oxidized intervention layer disposed over the floating gate; and a control gate disposed over the laterally oxidized intervention layer. The laterally oxidized intervention layer includes a sidewall portion and a center portion, wherein the sidewall portion has an oxygen concentration greater than that of the center portion.

### CROSS-REFERENCE TO RELATED APPLICATION

This application is a continuation-in-part application of U.S. Non-Provisional application Ser. No. 18/409,990 filed Jan. 11, 2024, which is incorporated herein by reference in its entirety.

### TECHNICAL FIELD

The present disclosure relates to a semiconductor device and a method for fabricating the same, and more particularly, to a semiconductor device having a sidewall oxidized dielectric and the fabrication method thereof.

### DISCUSSION OF THE BACKGROUND

Semiconductor devices are used in various electronic applications, including personal computers, cell phones, digital cameras, and other electronic equipment. The size of semiconductor devices is continuously decreasing to meet the growing demand for computing power. However, scaling down presents challenges that are becoming more frequent and impactful. Therefore, there are still challenges to overcome in improving quality, yield, performance and reliability while reducing complexity.

This Discussion of the Background section is provided for background information only. The statements in this Discussion of the

Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device comprising a substrate; a tunnel insulating layer disposed over the substrate; a floating gate disposed over the tunnel insulating layer; a laterally oxidized intervention layer disposed over the floating gate; and a control gate disposed over the laterally oxidized intervention layer. The laterally oxidized intervention layer comprises a sidewall portion and a center portion, wherein the sidewall portion has an oxygen concentration greater than that of the center portion.

In some embodiments, the semiconductor device further comprises a plurality of doped regions disposed in the substrate.

In some embodiments, the semiconductor device further comprises a first well region in the substrate, wherein the plurality of doped regions are disposed in the first well region.

In some embodiments, the semiconductor device further comprises a plurality of memory unit spacers disposed on the substrate and attached to sidewalls of the tunnel insulating layer.

In some embodiments, the semiconductor device further comprises a memory top conductive layer disposed over the control gate.

In some embodiments, the laterally oxidized intervention layer has a thickness between 10 angstroms and about 350 angstroms.

In some embodiments, the tunnel insulating layer has a thickness different from the thickness of the laterally oxidized intervention layer, and the tunnel insulating layer is formed of a material different from a material of the laterally oxidized intervention layer.

In some embodiments, the semiconductor device further comprises a passivation insulating layer disposed on the substrate, wherein the passivation insulating layer covers the memory top conductive layer and the memory unit spacers.

In some embodiments, the semiconductor device further comprises a plurality of first doped region contacts extending from a top surface of the passivation insulating layer into the doped regions, wherein the first doped region contacts are electrically coupled to the doped regions.

In some embodiments, the first doped region contact comprises a lower portion and an upper portion, wherein the lower portion of the first doped region contact extends into the doped region, and the upper portion of the first doped region contact is surrounded by the passivation insulating layer.

In some embodiments, the lower portion of the first doped region contact has a first critical dimension, and the upper portion of the first doped region contact has a second critical dimension greater than the first critical dimension.

In some embodiments, the first critical dimension gradually decreases at positions of increasing distance from a top surface of the substrate, while the second critical dimension is constant.

In some embodiments, a peripheral surface of the lower portion of the first doped region contact is discontinuous with a peripheral surface of the upper portion of the first doped region contact.

In some embodiments, the lower portion of the first doped region contact and the upper portion of the first doped region contact are integrally formed.

In alternative embodiments, the semiconductor device comprises a plurality of second doped region contacts extending from the top surface of the passivation insulating layer to a top surface of the substrate, wherein the second doped region contacts are electrically coupled to the doped regions.

In some embodiments, the second doped region contact comprises a barrier layer and a conductive layer disposed over and surrounded by the barrier layer, wherein the passivation insulating layer surrounds the barrier layer of the second doped region contact.

In some embodiments, the barrier layer has a first thickness on sidewalls of the corresponding conductive layer and a second thickness under a bottom surface of the corresponding conductive layer, wherein the first thickness of the barrier layer is less than the second thickness of the barrier layer.

Another aspect of the present disclosure provides a semiconductor device comprising a substrate; a tunnel insulating layer disposed over the substrate; a floating gate disposed over the tunnel insulating layer; a laterally oxidized intervention layer disposed over the floating gate; a control gate disposed over the laterally oxidized intervention layer; and a selection unit disposed on the substrate. The selection unit comprises a selection unit insulating layer and a selection unit conductive layer.

In some embodiments, the laterally oxidized intervention layer comprises a sidewall portion and a center portion, wherein the sidewall portion has an oxygen concentration greater than that of the center portion.

In some embodiments, the selection unit is separated from the floating gate.

In some embodiments, the semiconductor device further comprises a plurality of doped regions disposed in the substrate.

In some embodiments, the semiconductor device further comprises a first well region in the substrate, wherein the plurality of doped regions are disposed in the first well region.

In some embodiments, the semiconductor device further comprises a plurality of selection unit spacers disposed on sidewalls of the selection unit.

In some embodiments, the semiconductor device further comprises a selection unit capping layer disposed over the selection unit.

In some embodiments, the selection unit insulating layer has a thickness between about 5 angstroms and about 50 angstroms.

In some embodiments, the selection unit conductive layer has a thickness between about 150 nm and about 300 nm.

In some embodiments, the semiconductor device further comprises a passivation insulating layer disposed on the substrate, wherein the passivation insulating layer covers the selection unit capping layer and the selection unit spacers.

In some embodiments, the semiconductor device further comprises a plurality of doped region contacts extending from a top surface of the passivation insulating layer to a top surface of the substrate, wherein the doped region contacts are electrically coupled to the doped regions.

In some embodiments, the doped region contact comprises a lower portion and an upper portion, wherein the lower portion of the doped region contact extends into the doped region, and the upper portion of the doped region contact is surrounded by the passivation insulating layer.

In some embodiments, the lower portion of the doped region contact has a first critical dimension, and the upper portion of the doped region contact has a second critical dimension greater than the first critical dimension.

In some embodiments, the first critical dimension gradually decreases at positions of increasing distance from the top surface of the substrate, while the second critical dimension is constant.

In some embodiments, a peripheral surface of the lower portion of the doped region contact is discontinuous with a peripheral surface of the upper portion of the doped region contact.

In some embodiments, the lower portion of the doped region contact and the upper portion of the doped region contact are integrally formed.

In some embodiments, the doped region contact comprises a barrier layer and a conductive layer disposed over and surrounded by the barrier layer, wherein the passivation insulating layer surrounds the barrier layer of the doped region contact.

In some embodiments, the barrier layer has a first thickness on sidewalls of the corresponding conductive layer and a second thickness under a bottom surface of the corresponding conductive layer, wherein the first thickness of the barrier layer is less than the second thickness of the barrier layer.

Another aspect of the present disclosure provides a method for fabricating a semiconductor device, comprising: providing a substrate; forming a first well region and an isolation structure in the substrate; forming a memory unit, a control unit, and a selection unit on the substrate; forming a plurality of doped regions in the substrate; performing a lateral oxidation process over the substrate; forming a plurality of memory unit spacers, a memory top conductive layer, a plurality of selection unit spacers, and a selection unit top conductive layer over the substrate; forming a passivation insulating layer on the substrate; and forming a plurality of doped region contacts in the passivation insulating layer.

In some embodiments, a process temperature of the lateral oxidation process is between about 300° C. and about 600° C.

In some embodiments, the memory unit comprises a tunnel insulating layer, a memory unit conductive layer, and a laterally oxidized intervention layer.

In some embodiments, the selection unit comprises a selection unit insulating layer and a selection unit conductive layer. In some embodiments, the doped region contact comprises a lower portion and an upper portion, wherein the lower portion of the doped region contact extends into the doped region, and the upper portion of the doped region contact is surrounded by the passivation insulating layer.

Due to the design of the semiconductor device of the present disclosure, a dielectric constant of the laterally oxidized intervention layer is increased. As a result, capacitive coupling between the control unit and the memory unit conductive layer becomes more effective. Therefore, the performance of the semiconductor device can be improved.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. The dimensions of the various features may be arbitrarily increased or reduced for clarity of discussion.

FIG. 1 is a top view of a semiconductor device in accordance with some embodiments of the present disclosure.

FIG. 2 is a cross-sectional view taken along a line A-A′ in FIG. 1 in accordance with one embodiment of the present disclosure.

FIG. 3 is a cross-sectional view taken along a line B-B′ in FIG. 1 in accordance with some embodiments of the present disclosure.

FIG. 4 is a cross-sectional view taken along a line A-A′ in FIG. 1 in accordance with various embodiments of the present disclosure.

FIG. 5 is a flowchart illustrating a method for fabricating a semiconductor device in accordance with some embodiments of the present disclosure.

FIG. 6 is a top view of an intermediate stage in a formation of a semiconductor device in accordance with some embodiments of the present disclosure.

FIG. 7 is a cross-sectional view taken along a line A-A′ in FIG. 6 in accordance with some embodiments of the present disclosure.

FIG. 8 is a cross-sectional view taken along a line B-B′ in FIG. 6 in accordance with some embodiments of the present disclosure.

FIG. 9 is a top view of an intermediate stage in a formation of a semiconductor device in accordance with some embodiments of the present disclosure.

FIG. 10 is a cross-sectional view taken along a line A-A′ in FIG. 9 in accordance with some embodiments of the present disclosure.

FIG. 11 is a cross-sectional view taken along a line B-B′ in FIG. 9 in accordance with some embodiments of the present disclosure.

FIG. 12 is a top view of an intermediate stage in a formation of a semiconductor device in accordance with some embodiments of the present disclosure.

FIG. 13 is a cross-sectional view taken along a line A-A′ in FIG. 12 in accordance with some embodiments of the present disclosure.

FIG. 14 is a cross-sectional view taken along a line B-B′ in FIG. 12 in accordance with some embodiments of the present disclosure.

FIG. 15 is a top view of an intermediate stage in a formation of a semiconductor device in accordance with some embodiments of the present disclosure.

FIG. 16 is a cross-sectional view taken along a line A-A′ in FIG. 15 in accordance with some embodiments of the present disclosure.

FIG. 17 is a cross-sectional view taken along a line B-B′ in FIG. 15 in accordance with some embodiments of the present disclosure.

FIG. 18 is a top view of an intermediate stage in a formation of a semiconductor device in accordance with some embodiments of the present disclosure.

FIG. 19 is a cross-sectional view taken along a line A-A′ in FIG. 18 in accordance with some embodiments of the present disclosure.

FIG. 20 is a cross-sectional view taken along a line B-B′ in FIG. 18 in accordance with some embodiments of the present disclosure.

FIG. 21 is a top view of an intermediate stage in a formation of a semiconductor device in accordance with some embodiments of the present disclosure.

FIG. 22 is a cross-sectional view taken along a line A-A′ in FIG. 21 in accordance with some embodiments of the present disclosure.

FIG. 23 is a cross-sectional view taken along a line B-B′ in FIG. 21 in accordance with some embodiments of the present disclosure.

FIG. 24 is a cross-sectional view taken along a line A-A′ in FIG. 21 in accordance with some embodiments of the present disclosure.

FIG. 25 is a cross-sectional view taken along a line B-B′ in FIG. 21 in accordance with some embodiments of the present disclosure.

FIG. 26 is a cross-sectional view taken along a line A-A′ in FIG. 21 in accordance with some embodiments of the present disclosure.

FIG. 27 is a cross-sectional view taken along a line B-B′ in FIG. 21 in accordance with some embodiments of the present disclosure.

FIG. 28 is a top view of an intermediate stage in a formation of a semiconductor device in accordance with some embodiments of the present disclosure.

FIG. 29 is a cross-sectional view taken along a line A-A′ in FIG. 28 in accordance with some embodiments of the present disclosure.

FIG. 30 is a cross-sectional view taken along a line B-B′ in FIG. 28 in accordance with some embodiments of the present disclosure.

FIGS. 31 to 35 are cross-sectional views taken along a line A-A′ in FIG. 28 in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features are formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures, do not necessarily mean an exactly identical orientation, layout, location, shape, size, amount, or other measure, but are intended to encompass nearly identical orientations, layouts, locations, shapes, sizes, amounts, or other measures within acceptable variations that may occur, for example, due to manufacturing processes. The term “substantially” may be used herein to reflect this meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the present disclosure, a semiconductor device generally means a device that can function by utilizing semiconductor characteristics, and an electro-optic device, a light-emitting display device, a memory device, a semiconductor circuit, and an electronic device are all included in the category of the semiconductor device.

It should be noted that in the description of the present disclosure, above (or up) corresponds to the direction of the arrow of the direction Z, and below (or down) corresponds to the opposite direction of the arrow of the direction Z.

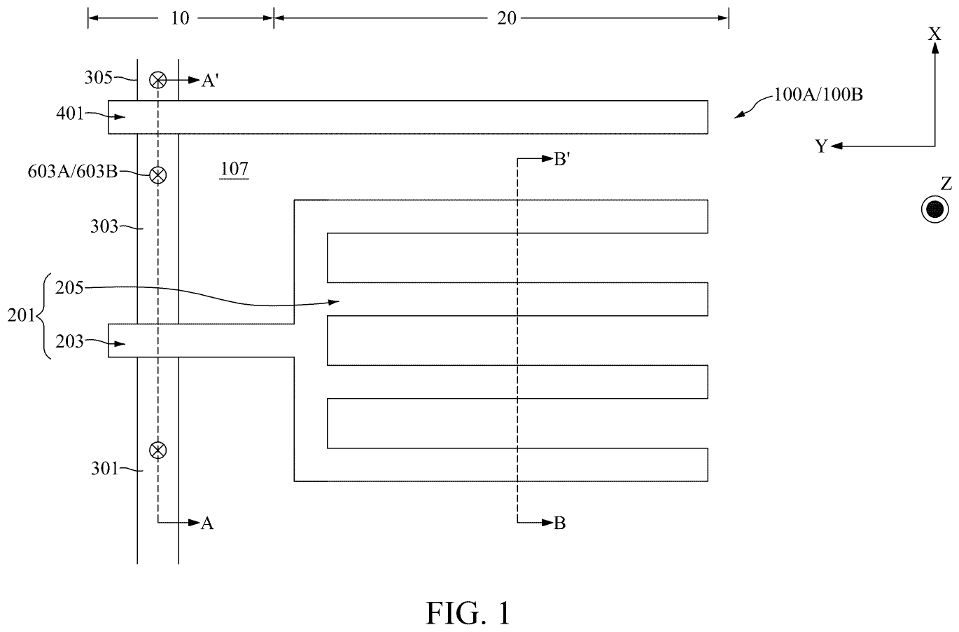

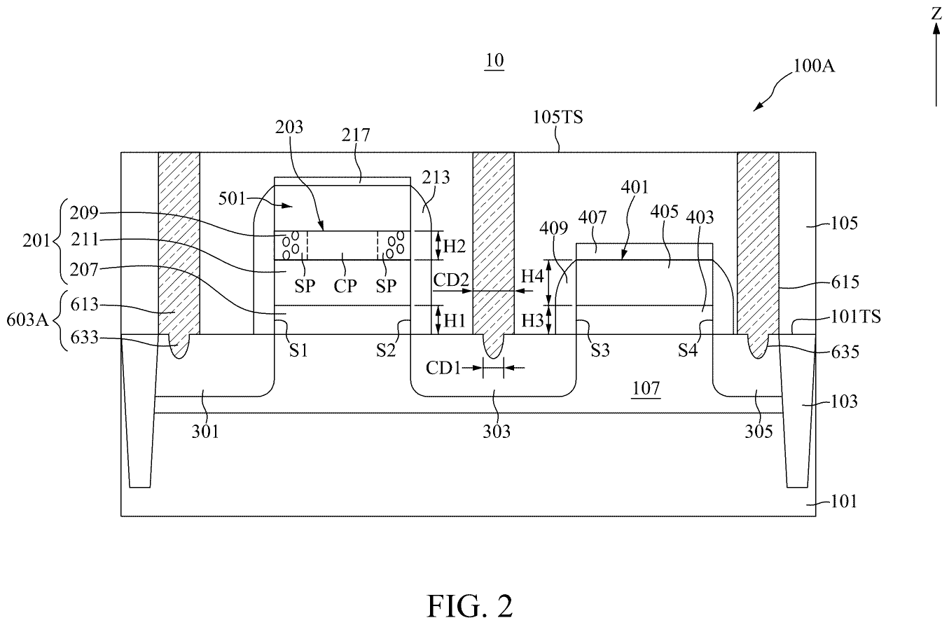

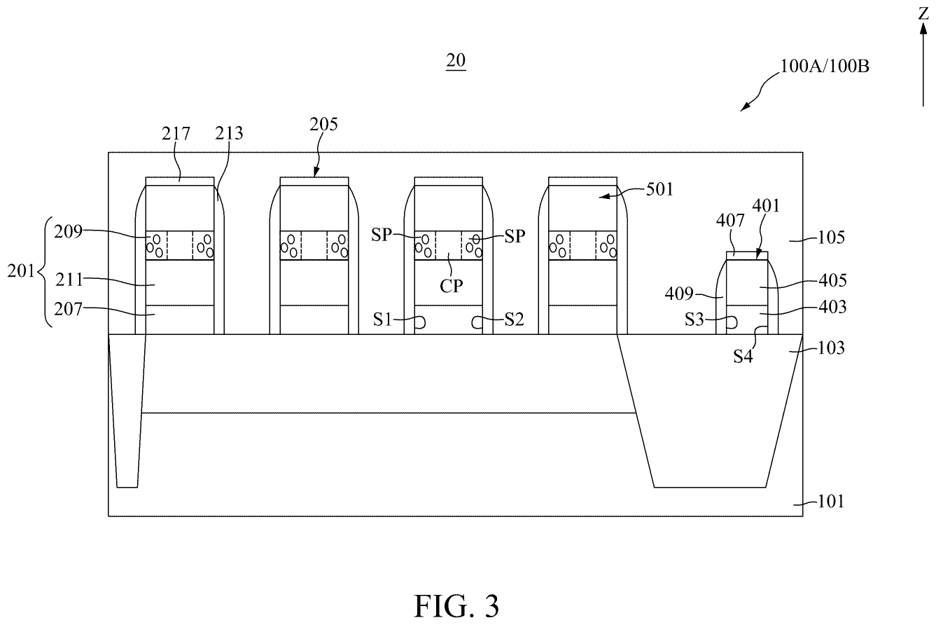

FIG. 1 is a top view of a semiconductor device 100A in accordance with some embodiments of the present disclosure. FIG. 2 is a cross-sectional view taken along a line A-A′ in FIG. 1. FIG. 3 is a cross-sectional view taken along a line B-B′ in FIG. 1.

Referring to FIGS. 1 to 3, the semiconductor device 100A includes a substrate 101, an isolation structure 103, a passivation insulating layer 105, a first well region 107, a memory unit 201, a memory top conductive layer 217, a first doped region 301, a second doped region 303, a third doped region 305, a selection unit 401, a selection unit top conductive layer 407, a control unit 501, and a doped region contact 603A.

Referring to FIGS. 1 to 3, the substrate 101 includes a first area 10 and a second area 20. The second area 20 is disposed adjacent to the first area 10. The substrate 101 is formed of, for example, silicon, doped silicon, germanium, silicon germanium, silicon carbon, silicon germanium carbon, gallium, gallium arsenic, indium arsenic, indium phosphorus, or other IV-IV, III-V or II-VI semiconductor materials. In some embodiments, the substrate 101 is formed of doped silicon and has a first electrical type. The substrate 101 is doped with a dopant such as boron.

It should be noted that the first area 10 may comprise a portion of the substrate 101 and a space above the portion of the substrate 101. Describing an element as being disposed on the first area 10 means that the element is disposed on a top surface of the portion of the substrate 101. Describing an element as being disposed in the first area 10 means that the element is disposed in the portion of the substrate 101; however, a top surface of the element may be level with the top surface of the portion of the substrate 101. Describing an element as being disposed above the first area 10 means that the element is disposed above the top surface of the portion of the substrate 101. Accordingly, the second area 20 may comprise another portion of the substrate 101 and a space above the other portion of the substrate 101.

Referring to FIGS. 1 to 3, the first well region 107 is disposed in the first area 10 and in the second area 20 of the substrate 101. The first well region 107 is doped with a dopant such as phosphorus, arsenic, or antimony and has a second electrical type.

Referring to FIGS. 1 to 3, the isolation structure 103 is disposed in the first area 10 and in the second area 20 of the substrate 101. In some embodiments, the isolation structure 103 is formed of, for example, an insulating material such as silicon oxide, silicon nitride, silicon oxynitride, silicon nitride oxide, or fluoride-doped silicate.

It should be noted that, in the present disclosure, silicon oxynitride refers to a substance that contains silicon, nitrogen, and oxygen and in which a proportion of oxygen is greater than that of nitrogen. Silicon nitride oxide refers to a substance that contains silicon, oxygen, and nitrogen and in which a proportion of nitrogen is greater than that of oxygen.

Referring to FIGS. 1 to 3, the memory unit 201 is disposed on the first area 10 and on the second area 2. The memory unit 201 includes a tunnel insulating layer 207, a memory unit conductive layer 211, and a laterally oxidized intervention layer 209. The memory unit 201 has sidewalls S1 and S2. That is, sidewalls of the tunnel insulating layer 207, sidewalls of the memory unit conductive layer 211, and sidewalls of the laterally oxidized intervention layer 209 are aligned with each other and coplanar at each side. The portion of the memory unit 201 that is disposed on the first area 10 is referred to as a handle portion 203. The portion of the memory unit 201 that is disposed on the second area 20 is referred to as a fork portion 205. In a top view, one end of the fork portion 205 is connected to the handle portion 203. The opposite end of the fork portion 205 is divided into four segments, and each of the four segments extends in a direction away from the handle portion 203 and opposite to a first direction Y. The four segments of the fork portion 205 are shown in the cross-sectional view of FIG. 3.

Referring to FIGS. 2 and 3, the tunnel insulating layer 207 is disposed on the first area 10 and on the second area 20 of the substrate 101. The tunnel insulating layer 207 has a thickness between about 30 angstroms and 130 angstroms. The tunnel insulating layer 207 is formed of, for example, silicon oxide, silicon nitride, silicon oxynitride, silicon nitride oxide, aluminum oxide, hafnium oxide, zirconium oxide, or a combination thereof.

Referring to FIGS. 2 and 3, the memory unit conductive layer 211 is disposed above the first area 10 and above the second area 20 of the substrate 101. The memory unit conductive layer 211 is respectively and correspondingly disposed on the tunnel insulating layer 207. The memory unit conductive layer 211 is formed of, for example, polysilicon or polysilicon-germanium.

Referring to FIGS. 2 and 3, the laterally oxidized intervention layer 209 is disposed above the first area 10 and above the second area 20 of the substrate 101. The laterally oxidized intervention layer 209 is respectively and correspondingly disposed on the memory unit conductive layer 211. The laterally oxidized intervention layer 209 is formed of, for example, an insulating material having a dielectric constant of about 4.0 or greater. Alternatively, in another embodiment, the insulating material is silicon oxide, silicon nitride, silicon oxynitride, silicon nitride oxide, or the like. At sidewall portions SP of the laterally oxidized intervention layer 209, the laterally oxidized intervention layer 209 has an oxygen concentration greater than an oxygen concentration at a center portion CP of the laterally oxidized intervention layer 209. The laterally oxidized intervention layer 209 has a thickness between 10 angstroms and about 350 angstroms. The laterally oxidized intervention layer 209 has a thickness H2 different from a thickness H1 of the tunnel insulating layer 207, and the laterally oxidized intervention layer 209 is formed of a material different from the material of the tunnel insulating layer 207.

Referring to FIGS. 2 and 3, the control unit 501 is disposed above the first area 10 and above the second area 20 of the substrate 101. The control unit 501 is respectively and correspondingly disposed on the laterally oxidized intervention layer 209. The control unit 501 is formed of, for example, polysilicon or polysilicon-germanium. Notably, from a sectional perspective view, sidewalls of the control unit 501 are substantially aligned with the sidewalls S1 and S2 of the memory unit.

Referring to FIGS. 2 and 3, the memory top conductive layer 217 is disposed above the first area 10 and above the second area 20 of the substrate 101. The memory top conductive layer 217 is respectively and correspondingly disposed on the control unit 501. The memory top conductive layer 217 is formed of, for example, metal silicide.

Referring to FIGS. 2 and 3, the memory unit spacer 213 is disposed on sidewalls of the control unit 501 and the sidewalls S1 and S2 of the memory unit 201. The memory unit spacer 213 is formed of, for example, silicon oxide, silicon nitride, silicon oxynitride, or silicon nitride oxide.

Referring to FIGS. 1 to 3, the selection unit 401 is disposed on the first area 10 and on the second area 20 of the substrate 101. The selection unit 401 is separated from the memory unit 201 along a second direction X that is perpendicular to the first direction Y. The selection unit 401 includes a selection unit insulating layer 403 and a selection unit conductive layer 405. The selection unit insulating layer 403 is disposed on the substrate 101. The selection unit conductive layer 405 is disposed on the selection unit insulating layer 403. The selection unit 401 has sidewalls S3 and S4. Sidewalls of the selection unit insulating layer 403 and sidewalls of the selection unit conductive layer 405 are aligned with each other and coplanar at each side. The selection unit insulating layer 403 has a thickness between about 5 angstroms and about 50 angstroms. It should be noted that the thickness of the selection unit insulating layer 403 can be set to an arbitrary range depending on the circumstances. The selection unit insulating layer 403 is formed of, for example, an insulating material having a dielectric constant of about 4.0 or greater. Alternatively, in some embodiments, the insulating material includes silicon oxide, silicon nitride, silicon oxynitride, silicon nitride oxide, or the like. The selection unit conductive layer 405 has a thickness between about 150 nm and about 300 nm. The selection unit conductive layer 405 is formed of, for example, doped polysilicon.

Referring to FIGS. 1 to 3, the selection unit top conductive layer 407 is disposed above the first area 10 and above the second area 20 of the substrate 101. The selection unit top conductive layer 407 is disposed on the selection unit conductive layer 405. The selection unit top conductive layer 407 is formed of, for example, metal silicide. The metal silicide includes nickel silicide, platinum silicide, titanium silicide, molybdenum silicide, cobalt silicide, tantalum silicide, tungsten silicide, or the like.

Referring to FIGS. 1 to 3, a selection unit spacer 409 is disposed on the sidewalls of the selection unit insulating layer 403 and on the sidewalls of the selection unit conductive layer 405 (i.e., the sidewalls S3 and S4 of the selection unit 401). The selection unit spacer 409 is formed of, for example, silicon oxide, silicon nitride, silicon oxynitride, or silicon nitride oxide.

Referring to FIG. 2, the first doped region 301, the second doped region 303, and the third doped region 305 are disposed in the first well region 107. The doped regions 303, 305 and 307 are doped with a dopant such as boron and thus have the first electrical type. The first doped region 301 is adjacent to one side of the tunnel insulating layer 207. A portion of a top surface of the first doped region 301 contacts a bottom of the tunnel insulating layer 207. The second doped region 303 is adjacent to an opposite side of the tunnel insulating layer 207. One side of the second doped region 303 contacts the bottom of the tunnel insulating layer 207. An opposite side of the second doped region 303 is adjacent to one side of the selection unit insulating layer 403. The third doped region 305 is adjacent to an opposite side of the selection unit insulating layer 403.

Referring to FIGS. 1 to 3, the doped region contact 603A is disposed on the first area 10 of the substrate 101. The doped region contact 603A extends from a top surface 105TS of the passivation insulating layer 105 into the first doped region 301, the second doped region 303 or the third doped region 305 and is electrically coupled to the first doped region 301, the second doped region 303 or the third doped region 305. The doped region contact 603A is disposed on either side of the handle portion 203 of the memory unit 201 or on either side of the selection unit 401.

More particularly, the doped region contact 603A includes a lower portion 633 extending into the first doped region 301, the second doped region 303 or the third doped region 305, and an upper portion 613 disposed in the passivation insulating layer 105. The upper portion 613 of the doped region contact 603A is surrounded by the passivation insulating layer 105.

Still referring to FIGS. 1 to 3, the lower portion 633 of the doped region contact 603A, which is lower than a top surface 101TS of the substrate 101, has a first critical dimension CD1, and the upper portion 613 of the doped region contact 603A, which is higher than the top surface 101TS of the substrate 101, has a second critical dimension CD2 greater than the first critical dimension CD1. In some embodiments, the first critical dimension CD1 gradually decreases at positions of increasing distance from the top surface 110TS of the substrate 101, while the second critical dimension CD2 is constant. In particular, a peripheral surface 635 of the lower portion 633 of the doped region contact 603A is discontinuous with a peripheral surface 615 of the upper portion 613 of the doped region contact 603A. Notably, the lower portion 633 and the upper portion 613 of the doped region contact 603A are integrally formed. The doped region contact 603A is formed of, for example, doped polysilicon, metal, metal nitride, or metal silicide.

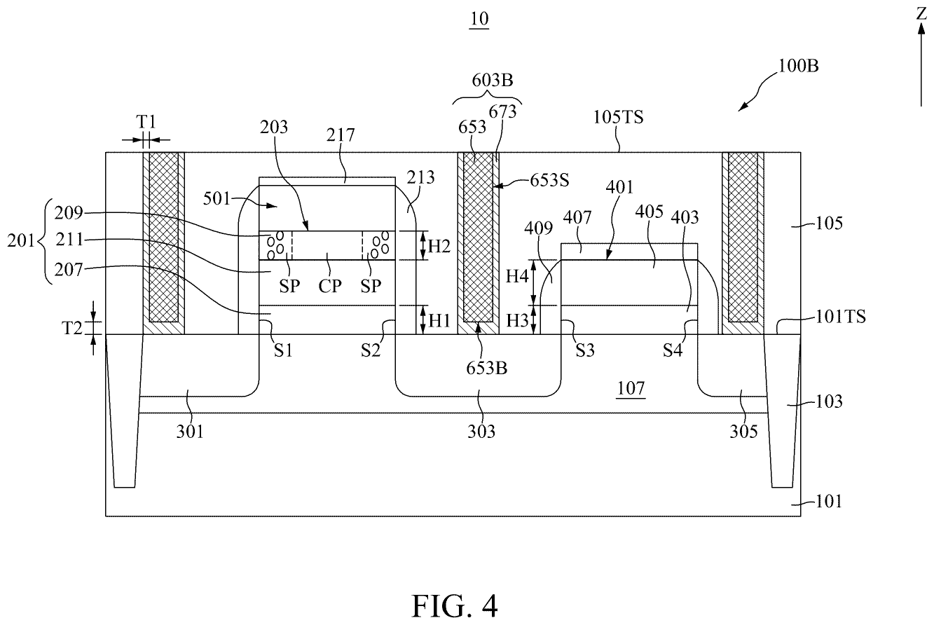

FIG. 4 is a cross-sectional view taken along a line A-A′ in FIG. 1 in accordance with another embodiment of the present disclosure.

Referring to FIGS. 1, 3, and 4, the semiconductor device 100B is similar to the semiconductor device 100A in many aspects, and description of similar features will not be repeated herein.

Referring to FIG. 4, the semiconductor device 100B includes a doped region contact 603B. The doped region contact 603B is disposed on the first area 10 of the substrate 101. The doped region contact 603B extends from the top surface 105TS of the passivation insulating layer 105 to the top surface 101TS of the substrate 101 and is electrically coupled to the first doped region 301, the second doped region 303 or the third doped region 305. The doped region contact 603B is disposed on either side of the handle portion 203 of the memory unit 201 or on either side of the selection unit 401.

More particularly, the doped region contact 603B includes a barrier layer 673 and a conductive layer 653 disposed over and surrounded by the barrier layer 673. The barrier layer 673 of the doped region contact 603B is surrounded by the passivation insulating layer 105.

Still referring to FIGS. 1, 3 and 4, the barrier layer 673 has a first thickness T1 on sidewalls 653S of the corresponding conductive layer 653, and a second thickness T2 under a bottom surface 653B of the corresponding conductive layer 653. In some embodiments, the barrier layer 673 is formed by an anisotropic deposition process, such that the first thickness T1 is less than the second thickness T2. In some embodiments, the anisotropic deposition process is a physical vapor deposition (PVD) process. The barrier layer 673 includes, for example, titanium (Ti), titanium nitride (TiN), or a combination thereof, and the conductive layer 653 includes tungsten (W). In some embodiments, the conductive layer 653 is separated from the passivation insulating layer 105, the first doped region 301, the second doped region 303, and the third doped region 305 by the barrier layer 673. In some embodiments, the conductive layer 653 is formed by a deposition process and a subsequent planarization process.

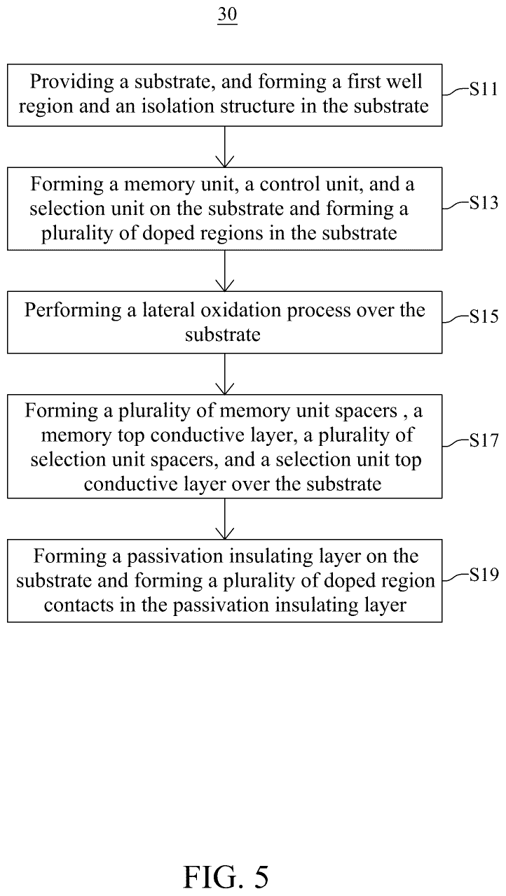

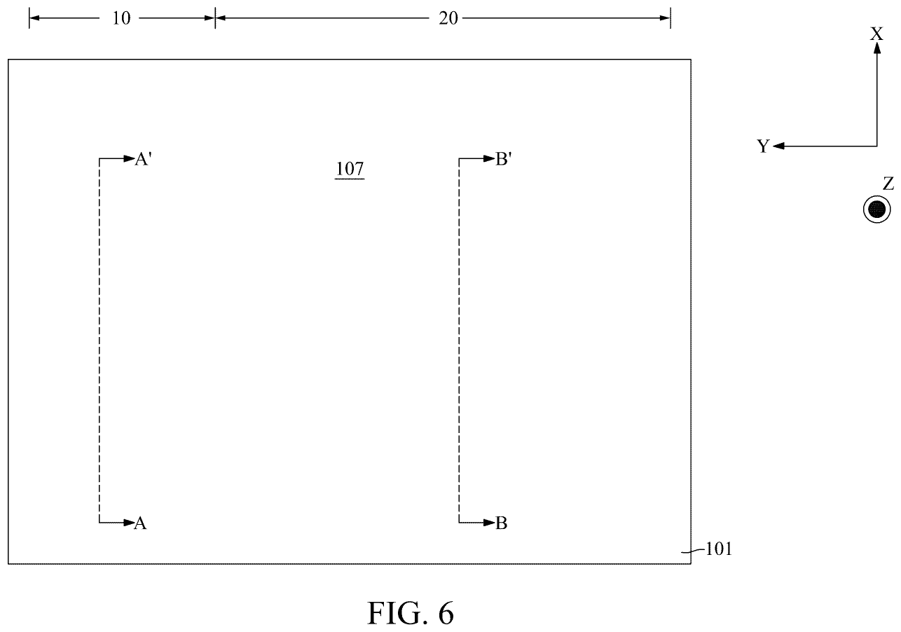

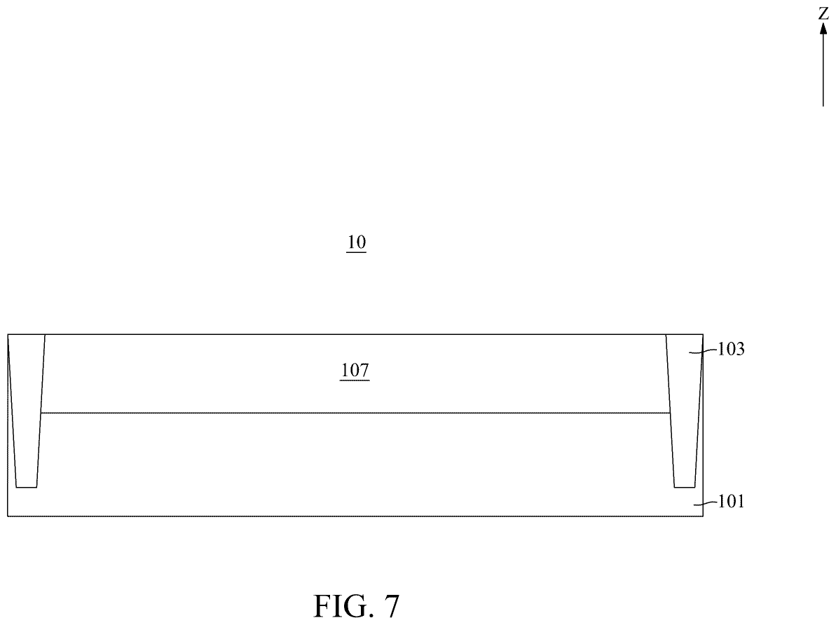

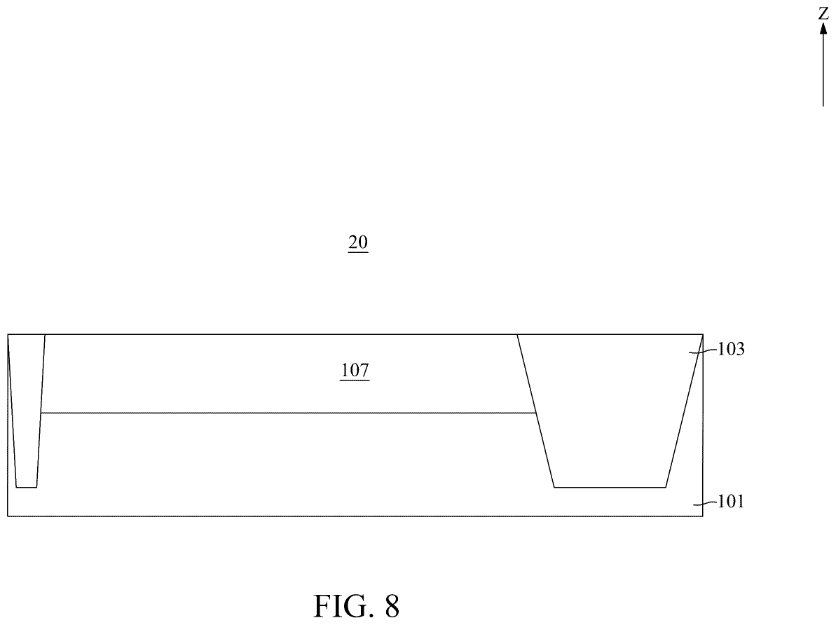

FIG. 5 is a flowchart illustrating a method 30 for fabricating the semiconductor device 100A in accordance with embodiments of the present disclosure. FIG. 6 is a top view of an intermediate stage in a formation of the semiconductor device 100A in accordance with the method 30. FIG. 7 is a cross-sectional view taken along a line A-A′ in FIG. 6. FIG. 8 is a cross-sectional view taken along a line B-B′ in FIG. 6.

Referring to FIG. 5 and FIGS. 6 to 8, in step S11, a substrate 101 is provided, and a first well region 107 and an isolation structure 103 are formed in the substrate 101. The substrate 101 includes a first area 10 and a second area 20 next to the first area 10. The first well region 107 is formed in the first area 10 and in the second area 20 by a single step implantation process or a multi-step implantation process. The isolation structure 103 is formed in the first area 10 and in the second area 20.

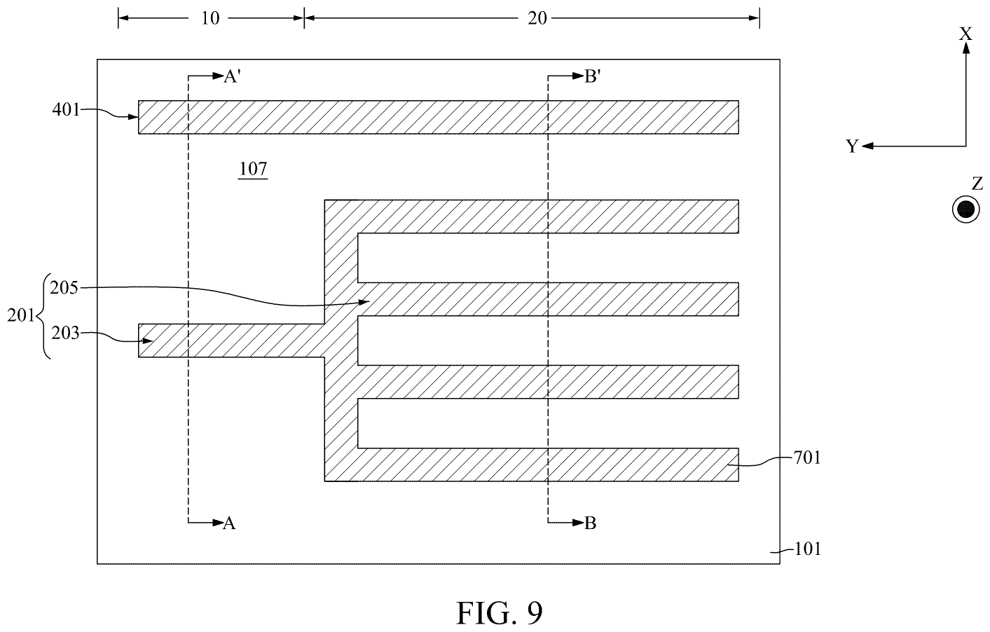

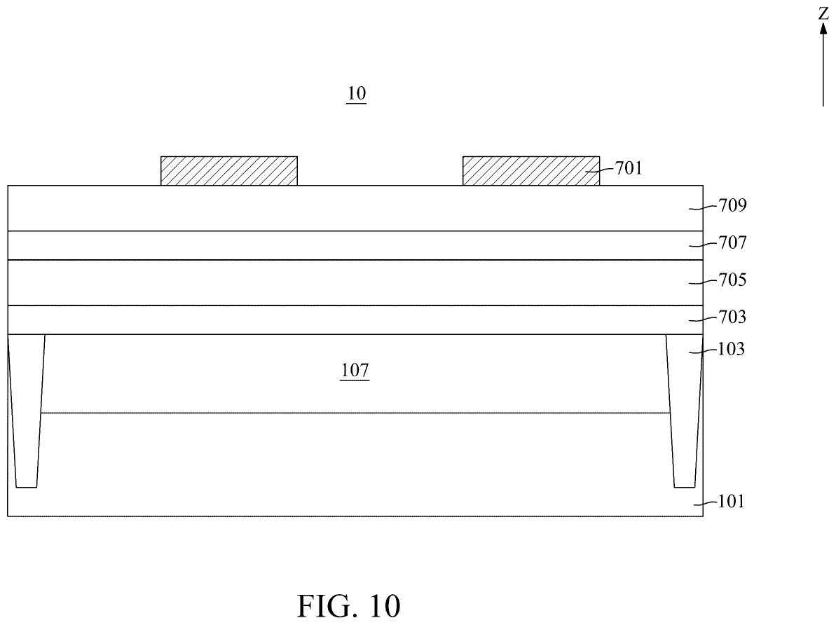

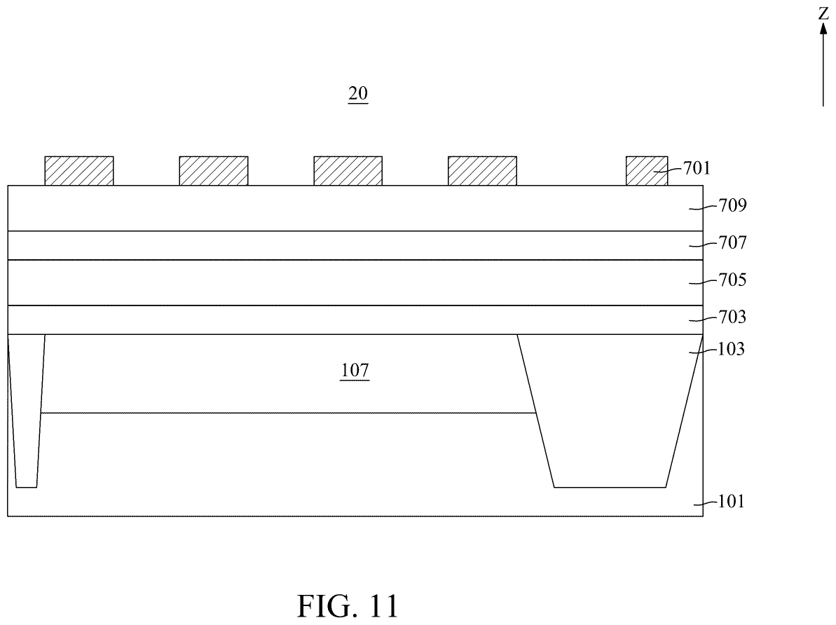

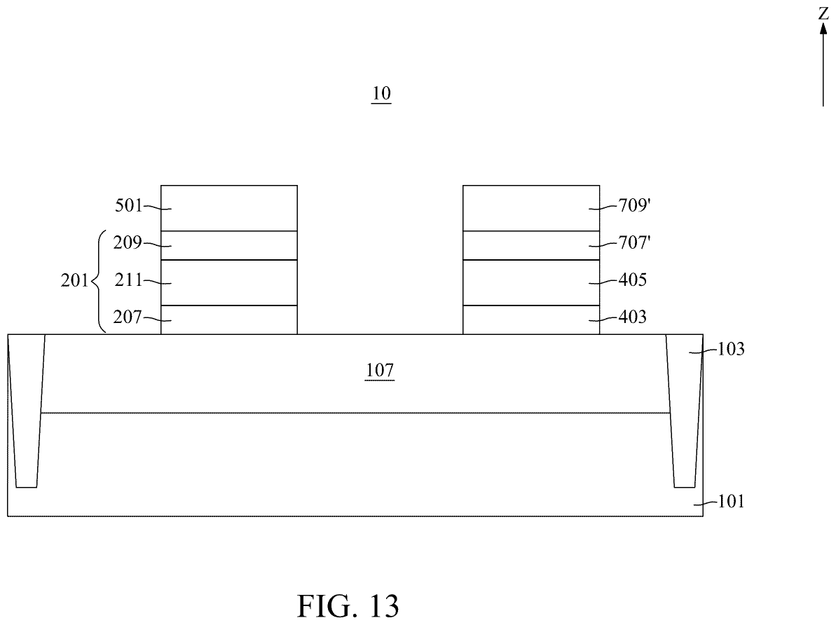

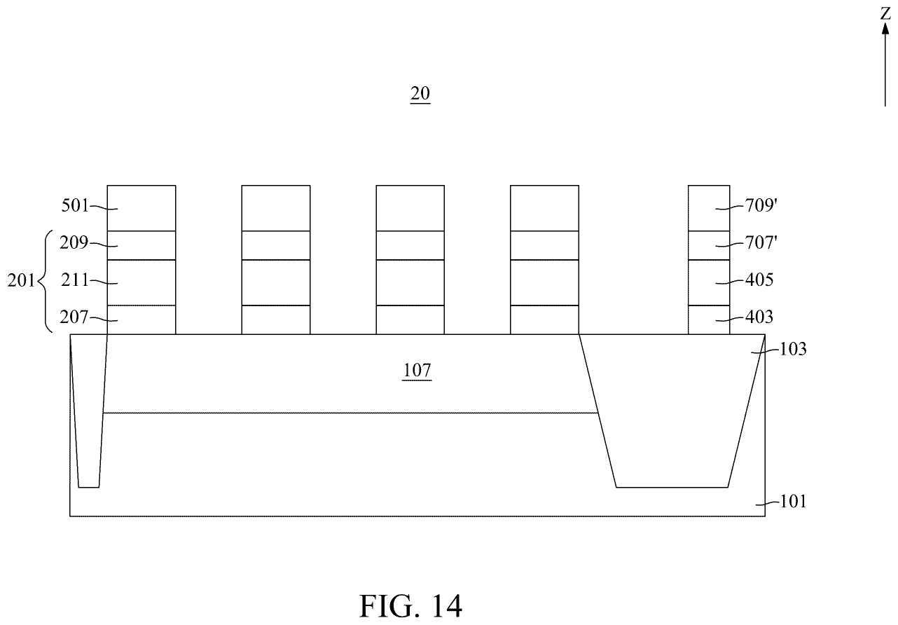

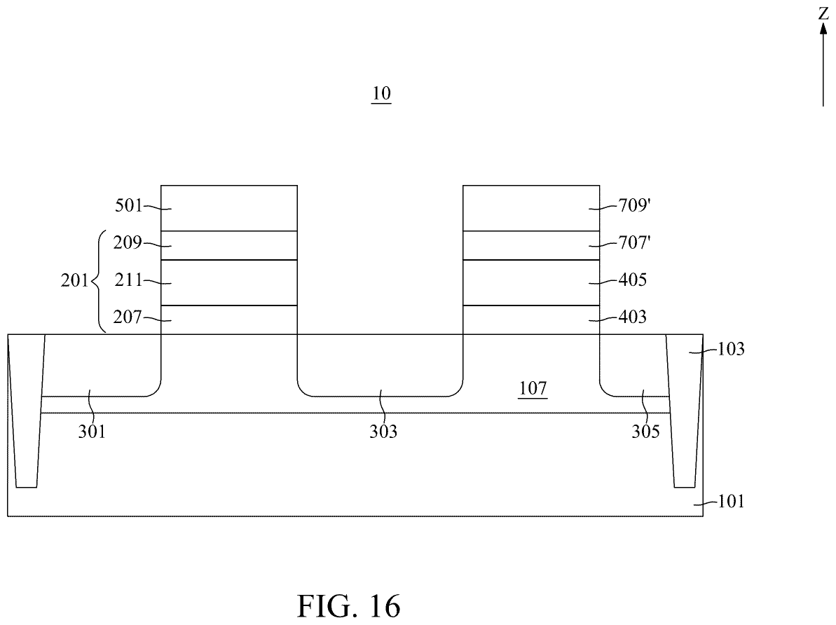

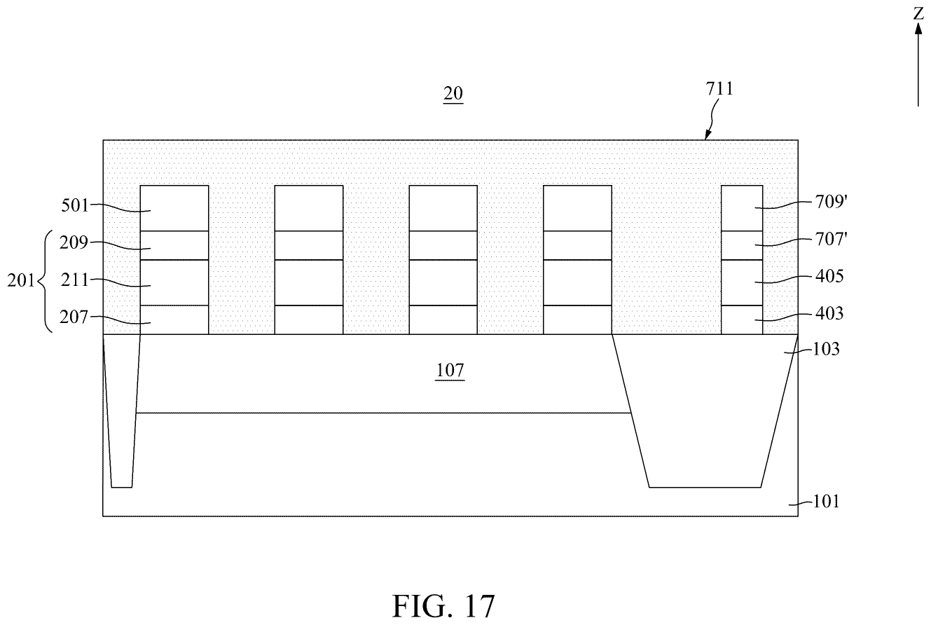

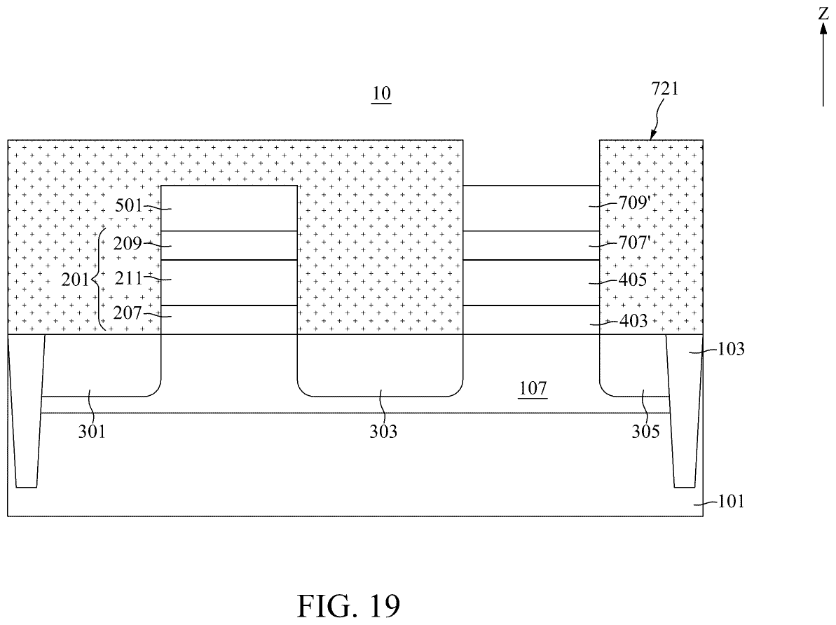

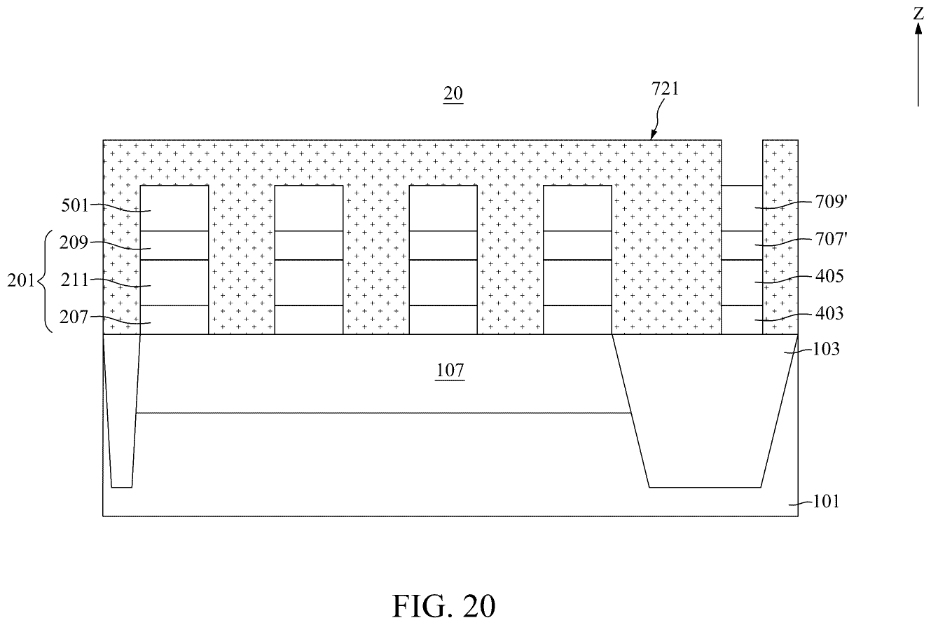

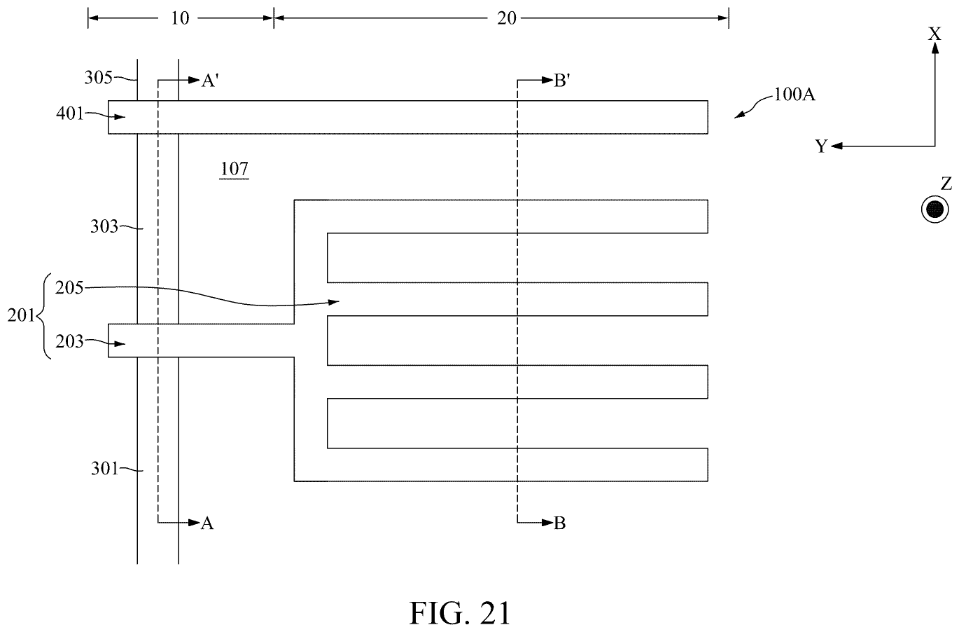

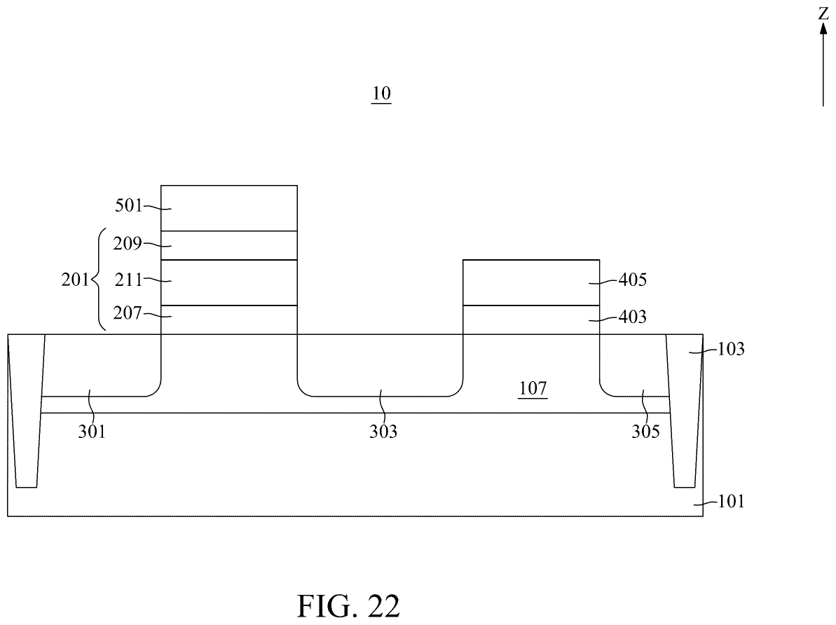

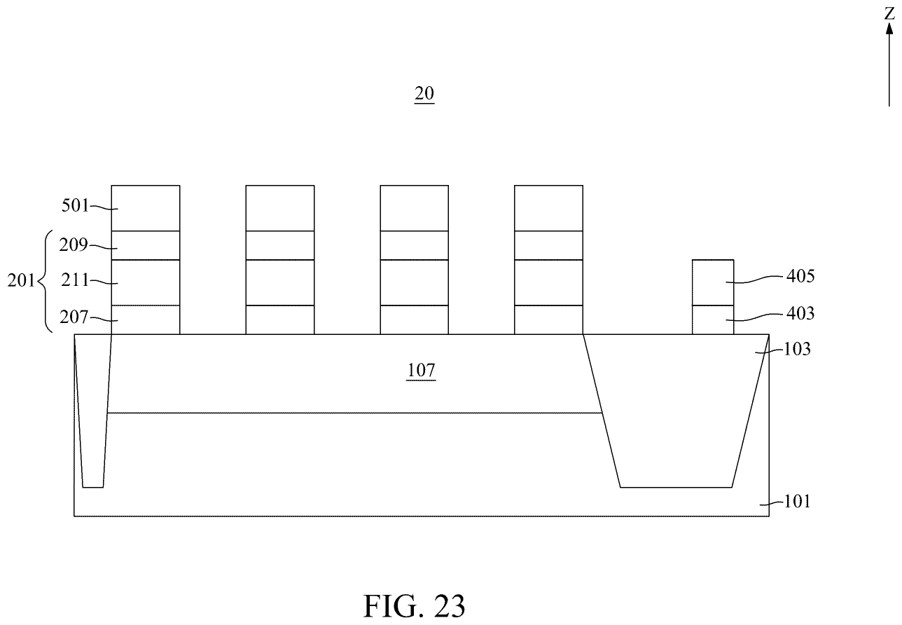

FIGS. 9, 12, 15, 18 and 21 are top views of intermediate stages in a formation of the semiconductor device 100A in accordance with the method 30. FIGS. 10, 13, 16, 19 and 22 are cross-sectional views taken along a line A-A′ in FIGS. 9, 12, 15, 18 and 21, respectively. FIGS. 11, 14, 17, 20 and 23 are cross-sectional views taken along a line B-B′ in FIGS. 9, 12, 15, 18 and 21, respectively.

Referring to FIG. 5 and FIGS. 9 to 23, in step S13, a memory unit 201, a control unit 501 and a selection unit 401 are formed on the substrate 101, and a plurality of doped regions 301, 303 and 305 are formed in the substrate 101.

Referring to FIGS. 9 to 11, a bottom insulating layer 703, a bottom conductive layer 705, an intervention layer 707 and a top conductive layer 709 are sequentially deposited on the substrate 101. The bottom insulating layer 703 is formed of, for example, an insulating material having a dielectric constant of about 4.0 or greater. Alternatively, in some embodiments, the insulating material includes silicon oxide, silicon nitride, silicon oxynitride, silicon nitride oxide, or the like. The bottom conductive layer 705 is formed of, for example, polysilicon or polysilicon-germanium. The intervention layer 707 is formed of a material different from the material of the bottom insulating layer 703. The intervention layer 707 is formed of, for example, an insulating material having a dielectric constant of about 4.0 or greater. (All dielectric constants mentioned herein are relative to a vacuum unless otherwise noted.) The insulating material having a dielectric constant of about 4.0 or greater is, for example, hafnium oxide, zirconium oxide, aluminum oxide, titanium oxide, lanthanum oxide, strontium titanate, lanthanum aluminate, yttrium oxide, gallium (III) trioxide, gadolinium gallium oxide, lead zirconium titanate, barium strontium titanate, or a mixture thereof. The top conductive layer 709 is formed of, for example, polysilicon or polysilicon-germanium. A photolithography process using a first mask layer 701 is performed to define the positions of the memory unit 201 and the selection unit 401.

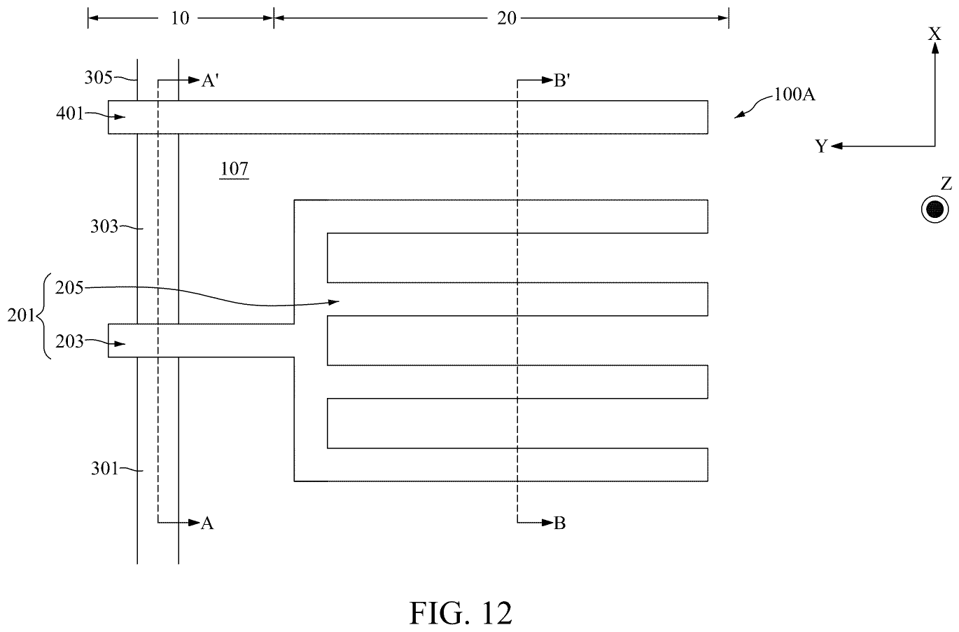

Referring to FIGS. 12 to 14, after the photolithography process, an etch process, such as an anisotropic dry etch process, is performed to remove portions of the top conductive layer 709, the intervention layer 707, the bottom conductive layer 705, and the bottom insulating layer 703. Remaining portions are left in place to form the handle portion 203, the fork portion 205, and the selection unit 401. After the etch process, the bottom insulating layer 703 in the handle portion 203 and the fork portion 205 is turned into a tunnel insulating layer 207 on the first area 10 and on the second area 20, the bottom conductive layer 705 in the handle portion 203 and the fork portion 205 is turned into a memory unit conductive layer 211 on the first area 10 and on the second area 20, the intervention layer 707 in the handle portion 203 and the fork portion 205 is turned into a laterally oxidized intervention layer 209 on the first area 10 and on the second area 20, and the top conductive layer 709 in the handle portion 203 and the fork portion 205 is turned into the control unit 501 on the first area 10 and on the second area 20. In addition, on the first area 10 and on the second area 20, a portion of the bottom insulating layer 703 is turned into a selection unit insulating layer 403, a portion of the bottom conductive layer 705 is turned into a selection unit conductive layer 405, a portion of the intervention layer 707 is turned into an intervention layer 707′, and a portion of the top conductive layer 709 is turned into a top conductive layer 709′.

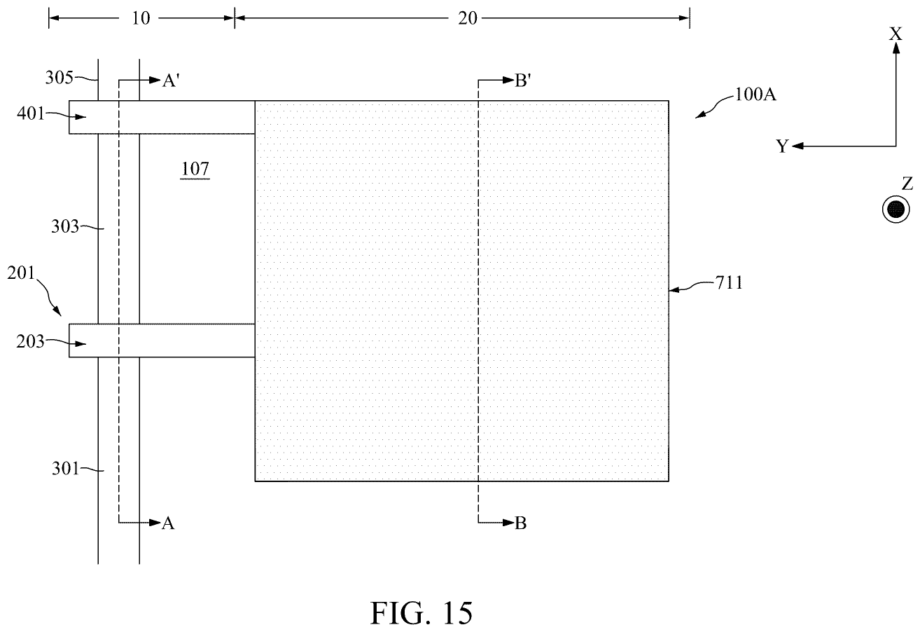

Referring to FIGS. 15 to 17, a second mask layer 711 is patterned to mask the second area 20. An implantation process is performed to form the plurality of doped regions in the first well region 107. The doped regions may include a first doped region 301, a second doped region 303, and a third doped region 305. The first doped region 301 and the second doped region 303 are respectively correspondingly formed adjacent to sidewalls of the tunnel insulating layer 207. The second doped region 303 is formed between the tunnel insulating layer 207 and the selection unit insulating layer 403. The third doped region 305 is formed opposite to the second doped region 303 and adjacent to one sidewall of the selection unit insulating layer 403. After the implantation process, the second mask layer 711 is removed.

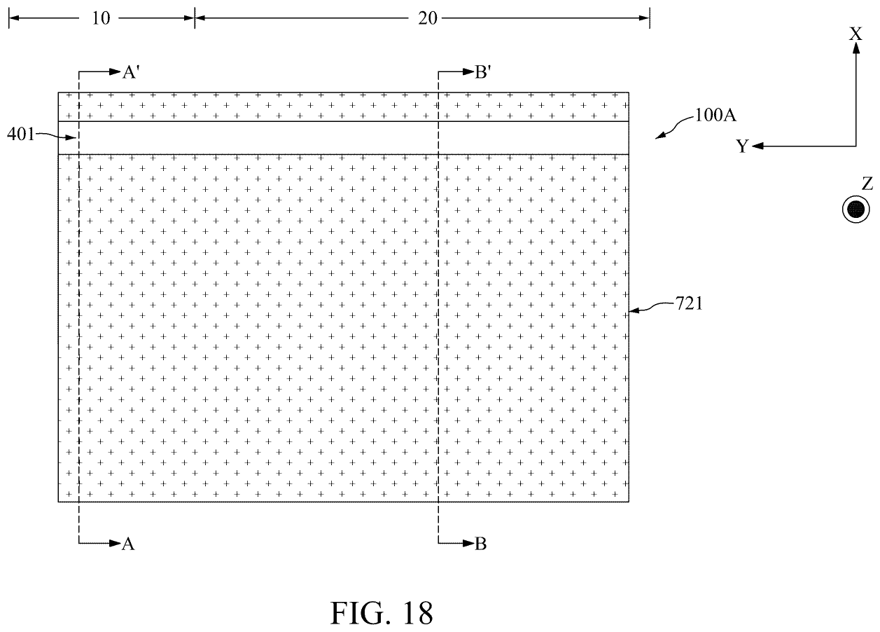

Referring to FIGS. 18 to 23, a third mask layer 721 is patterned to mask the areas outside of the selection unit 401 from a top-view perspective. After the formation of the mask layer 721, an etch process, such as an anisotropic dry etch process, is performed to remove the intervention layer 707′ and the top conductive layer 709′ on the first area 10 and the second area 20. After the etch process, the third mask layer 721 is removed.

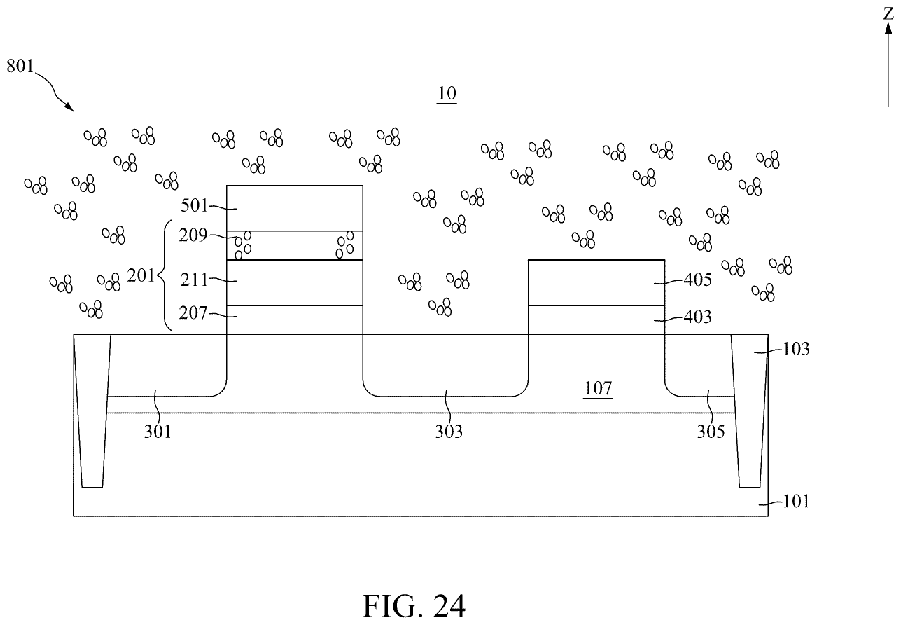

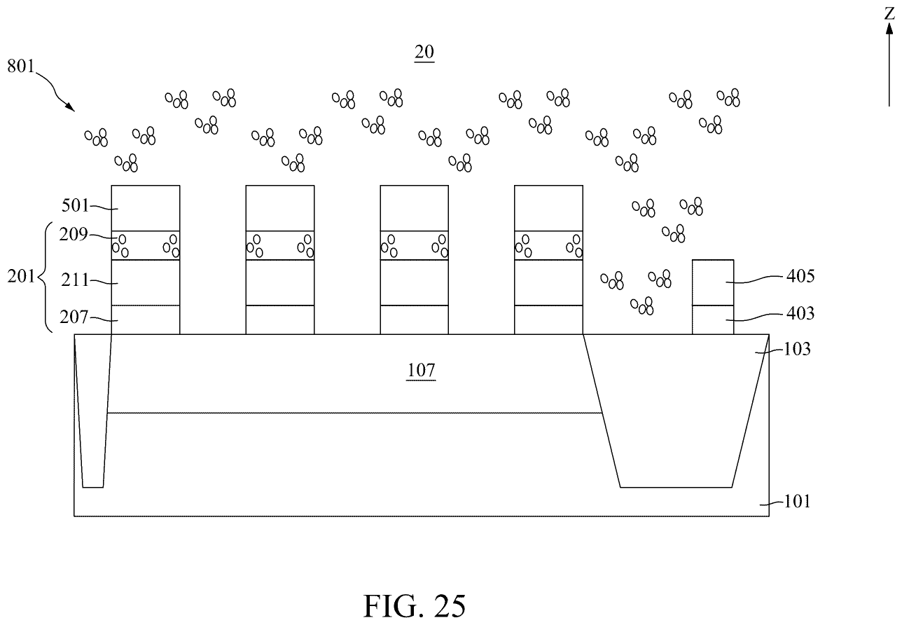

Referring to FIG. 5 and FIGS. 24 to 25, at step S15, a lateral oxidation process is performed over the substrate 101 to oxidize the laterally oxidized intervention layer 209. During the lateral oxidation process, the intermediate semiconductor device is placed in an oxidizing environment including oxidizing species 801 (indicated by groups of small circles in FIGS. 24 and 25). The oxidizing species 801 diffuse into the laterally oxidized intervention layer 209 from sidewalls thereof and fill oxygen vacancies in the laterally oxidized intervention layer 209. A process temperature of the lateral oxidation process is between about 300° C. and about 600° C. Preferably, the process temperature of the lateral oxidation process is between about 400° C. and about 500° C. A partial pressure of oxygen of the lateral oxidation process is between about 100 mTorr and about 20 atm. Preferably, the partial pressure of oxygen of the lateral oxidation process is between about 0.1 atm and about 1.0 atm. A duration of the lateral oxidation process is between about 10 minutes and about 6 hours. After the lateral oxidation process, threshold voltages of the laterally oxidized intervention layer 209 are increased. The oxidizing species 801 are molecules including oxygen such as molecular oxygen, water vapor, nitric oxide, or nitrous oxide. The process temperature of the lateral oxidation process, the partial pressure of oxygen of the lateral oxidation process, and the duration of the lateral oxidation process may together determine an extent of oxidation of the laterally oxidized intervention layer 209.

After the lateral oxidation process, an oxygen concentration at sidewall portions of the laterally oxidized intervention layer 209 is greater than an oxygen concentration at a center portion of the laterally oxidized intervention layer 209. It should be noted that other partial pressures of oxygen of the lateral oxidation process that are greater than or lesser than the aforementioned partial pressure of oxygen of the lateral oxidation process are also employed. Other durations of the lateral oxidation process that are greater than or lesser than the aforementioned duration of the lateral oxidation process are also employed. In general, the duration of the lateral oxidation process may decrease with an increase in either the process temperature of the lateral oxidation process or the partial pressure of oxygen of the lateral oxidation process. Alternatively, in another embodiment, when a greater duration of the lateral oxidation process is applied, the oxygen concentrations at the sidewall portions and the center portion of the laterally oxidized intervention layer 209 may all be increased. In some embodiments, the oxygen concentration at the sidewall portions of the laterally oxidized intervention layer 209 may be equal to the oxygen concentration at the center portion of the laterally oxidized intervention layer 209.

Referring to FIG. 5 and FIGS. 26 to 27, in step S17, a plurality of memory unit spacers 213, a plurality of selection unit spacers 409, a memory top conductive layer 217, and a selection unit top conductive layer 407 are formed above the substrate 101. A spacer layer (not shown) is formed over the substrate 101. The spacer layer may cover top surfaces of the control unit 501 and the selection unit conductive layer 405 and may cover sidewalls of the control unit 501, sidewalls of the memory unit 201 (i.e., the sidewalls of the laterally oxidized intervention layer 209, the memory unit conductive layer 211 and the tunnel insulating layer 207) and sidewalls of the selection unit 401 (i.e., sidewalls of the selection unit conductive layer 405 and the selection unit insulating layer 403). An etch process, such as an anisotropic dry etch process, is performed on portions of the spacer layer and may concurrently form the plurality of memory unit spacers 213 and the plurality of selection unit spacers 409.

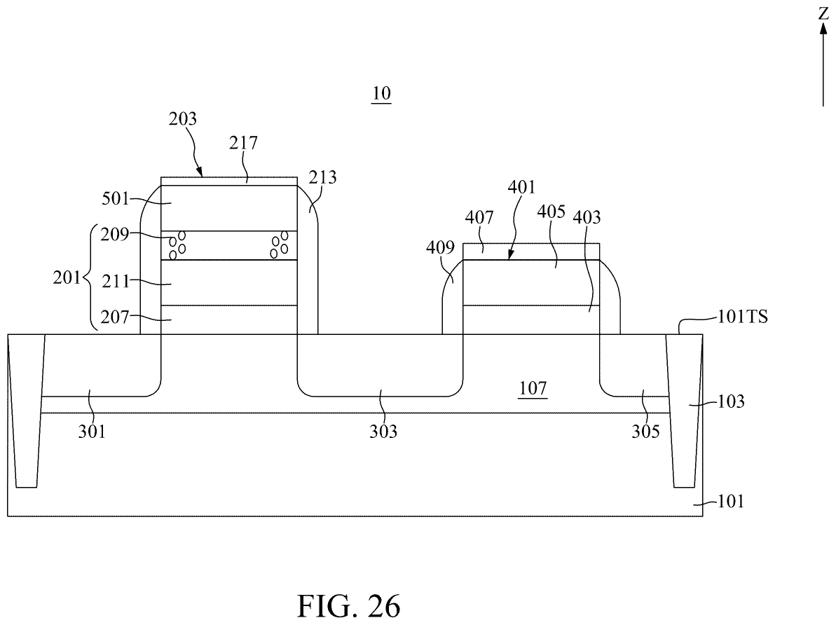

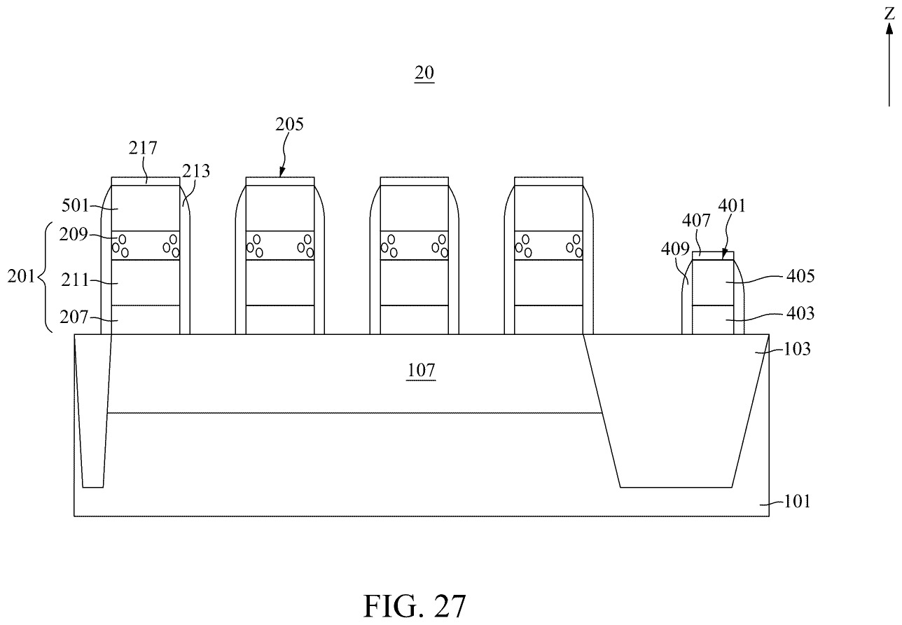

Referring to FIGS. 26 and 27, a self-aligned silicide process is performed to form the memory top conductive layer 217 on the control unit 501 and the selection unit top conductive layer 407 on the selection unit conductive layer 405.

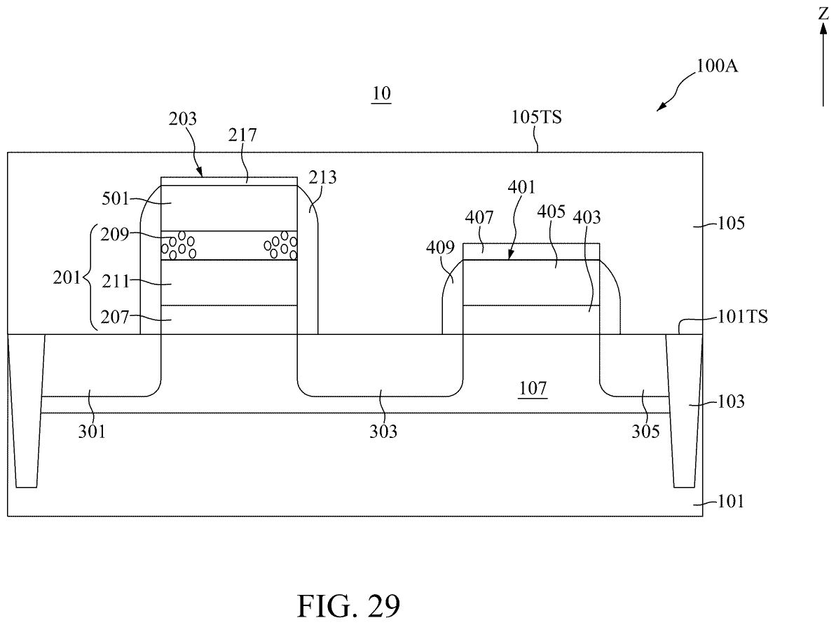

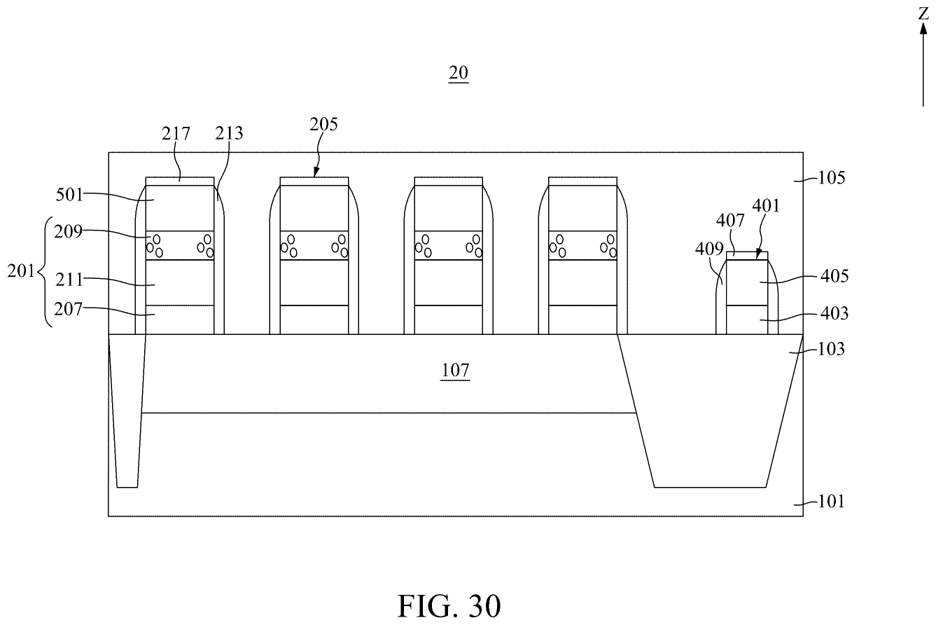

Referring to FIG. 5 and FIGS. 28 to 35, in step S19, a passivation insulating layer 105 is formed on the substrate 101, and a plurality of doped region contacts 603A are formed in the passivation insulating layer 105.

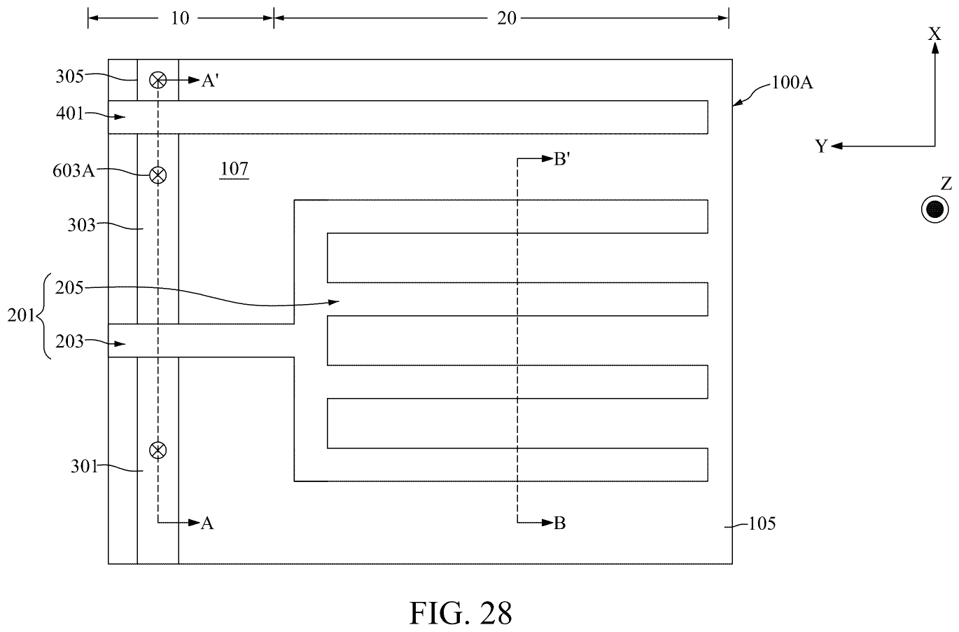

Referring to FIGS. 28 to 30, the passivation insulating layer 105 is formed to cover the memory top conductive layer 217, the memory unit spacer 213, the selection unit top conductive layer 407, and the selection unit spacer 409. A planarization process, such as chemical mechanical polishing, is performed on the passivation insulating layer 105 to provide a substantially flat surface for subsequent processing steps.

Referring to FIG. 28 and FIGS. 31 to 35, the plurality of doped region contacts 603A may subsequently be formed on the plurality of doped regions 301, 303 and 305 on the first area 10.

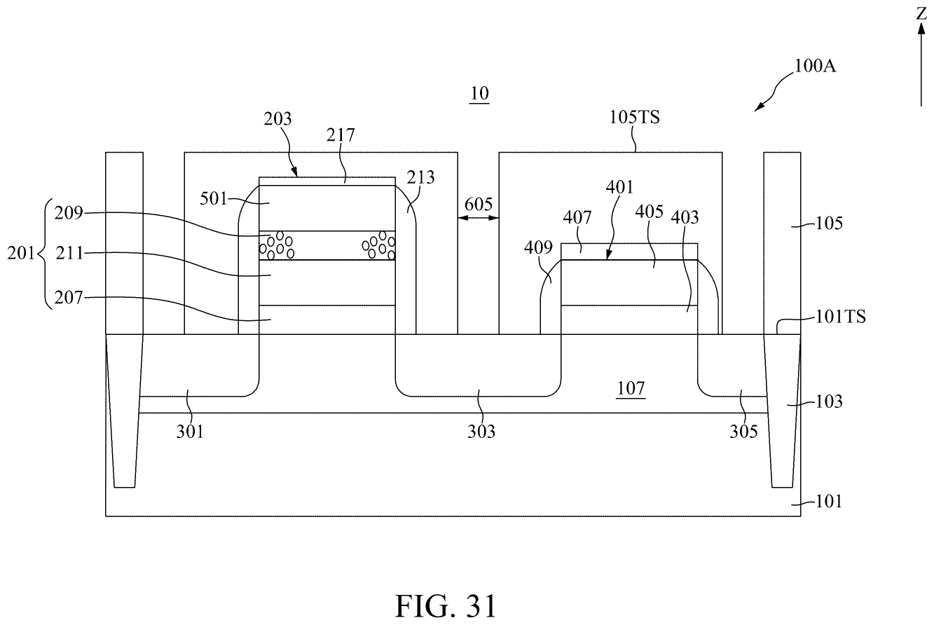

Referring to FIG. 31, an etch process, such as an anisotropic dry etch process, is performed on portions of the passivation insulating layer 105, thus forming a plurality of first contact holes 605 exposing the doped regions 301, 303 and 305.

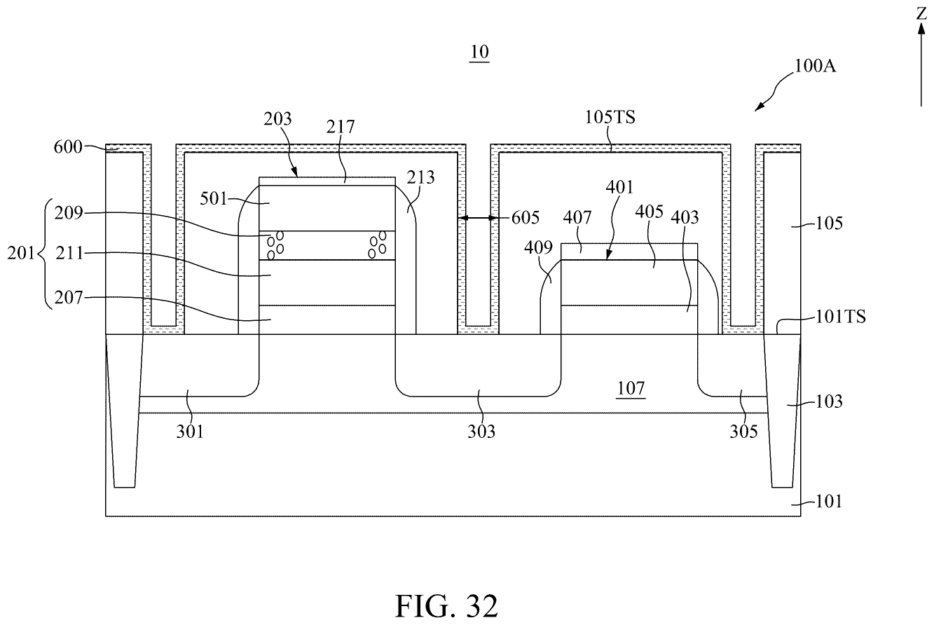

Referring to FIG. 32, a sacrificial film 600 is conformally formed on exposed portions of the passivation insulating layer 105 and on exposed portions of the doped regions 301, 303 and 305. The sacrificial film 600 has a substantially uniform thickness and a topology following topologies of the exposed portions of the passivation insulating layer 105 and the doped regions 301, 303 and 305. Notably, the sacrificial film 600 includes a dielectric material having etch characteristics different from those of the substrate 101. For example, the sacrificial film 600 can include nitride and be deposited using a CVD process, an ALD process, or the like.

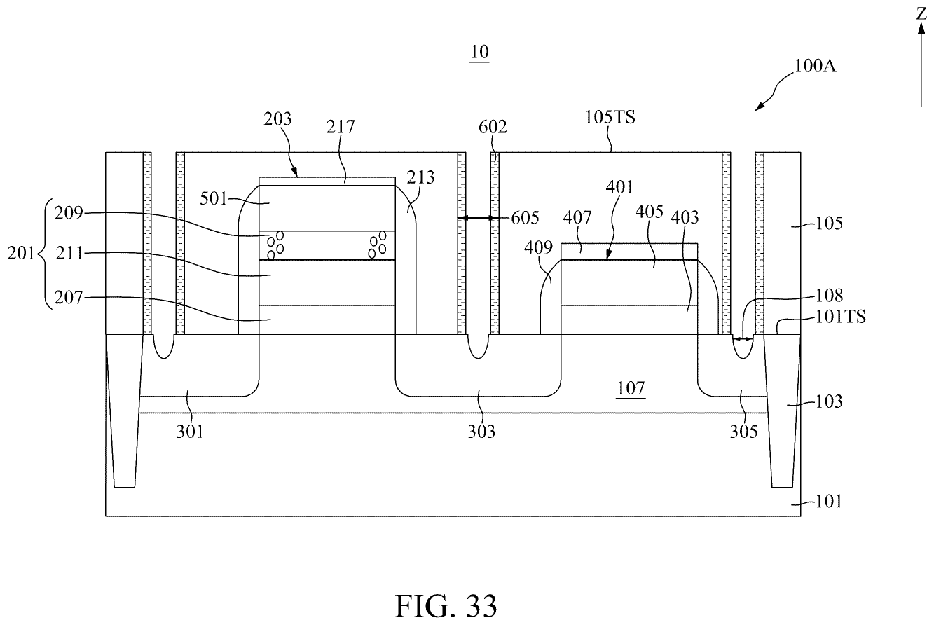

Referring to FIG. 33, a removal process is performed to remove at least portions of the sacrificial film 600 covering the doped regions 301, 303 and 305. Specifically, an anisotropic etching process is performed to remove horizontal portions of the sacrificial film 600 on the doped regions 301, 303 and 305 and over the passivation insulating layer 105, while vertical portions of the sacrificial film 600 are left on the passivation insulating layer 105, thereby forming a plurality of sacrificial liners 602 in the first contact holes 605. The horizontal portions of the sacrificial film 600 are removed using an anisotropic etching process. The chemistry of the anisotropic etching process can be selective to the material of the sacrificial film 600. In other words, no substantial quantities of the materials of the substrate 101 and the passivation insulating layer 105 are removed during the etching of the horizontal portions of the sacrificial film 600.

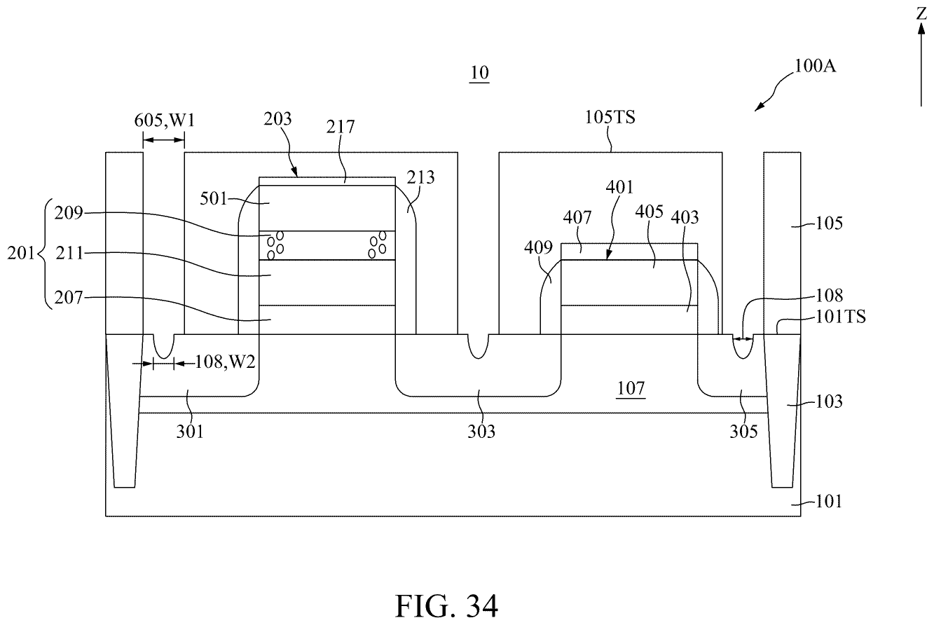

Referring to FIG. 34, portions of the doped regions 301, 303 and 305 exposed through the passivation insulating layer 105 and the sacrificial liners 602 are etched away. As a result, a plurality of second contact holes 108 connected to the first contact holes 605 are formed.

The portions of the doped regions 301, 303 and 305 exposed through the passivation insulating layer 105 and the sacrificial liners 602 are anisotropically dry-etched, using at least one reactive ion etching (RIE) process, for example, through the first contact holes 605 to form the second contact hole 108 in the doped regions 301, 303 and 305.

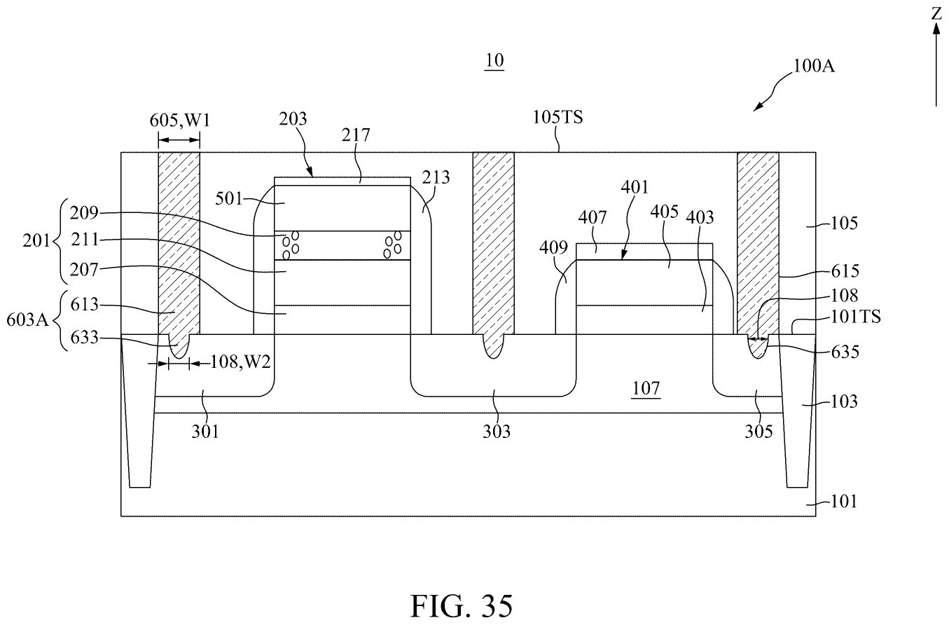

Referring to FIGS. 34 and 35, after the formation of the second contact holes 108, the sacrificial liners 602 are removed, and a conductive material is deposited in the first contact holes 605 and the second contact holes 108 to form the doped region contacts 603A. The sacrificial liners 602 are removed using a stable process such as a wet etching process. As shown in FIG. 34, the first contact holes 605 have a substantially uniform first width W1, and the second contact holes 108 have a non-uniform second width W2. In some embodiments, the second width W2 gradually decreases at positions of increasing distance from a top surface 101TS of the substrate 101. The doped region contacts 603A, including polysilicon, are deposited in the first and second contact holes 605 and 108 using a CVD process, for example. A portion of the doped region contacts 603A in the substrate 101 may have a funnel shape. Notably, portions of the doped region contacts 603A surrounded by the passivation insulating layer 105 may have a greater critical dimension once the sacrificial liner 602 is removed; as a result, resistances of the passivation insulating layer 105 can be reduced. However, in some embodiments, the sacrificial liner 602 is left in the resulting semiconductor device 100A if the material of the passivation insulating layer 105 has an acceptable resistivity. In such embodiments, a diffusion barrier layer, having a substantially uniform thickness, is deposited on the exposed portion of the substrate 101 and the sacrificial liners 602 to prevent the passivation insulating layer 105 from flaking or spalling from the sacrificial liners 602.

Referring to FIG. 35, the doped region contact 603A includes a lower portion 633 extending into the first doped region 301, the second doped region 303 or the third doped region 305, and an upper portion 613 disposed in the passivation insulating layer 105. The upper portion 613 of the doped region contact 603A is surrounded by the passivation insulating layer 105.

Due to the design of the semiconductor device 100A of the present disclosure, a dielectric constant of the laterally oxidized intervention layer 209 can be increased. As a result, capacitive coupling between the control unit 501 and the memory unit 201 may become more effective. Therefore, performance of the semiconductor device 100A can be improved.

One aspect of the present disclosure provides a semiconductor device comprising a substrate; a tunnel insulating layer disposed over the substrate; a floating gate disposed over the tunnel insulating layer; a laterally oxidized intervention layer disposed over the floating gate; and a control gate disposed over the laterally oxidized intervention layer. The laterally oxidized intervention layer comprises a sidewall portion and a center portion, wherein the sidewall portion has an oxygen concentration greater than that of the center portion.

Another aspect of the present disclosure provides a semiconductor device comprising a substrate; a tunnel insulating layer disposed over the substrate; a floating gate disposed over the tunnel insulating layer; a laterally oxidized intervention layer disposed over the floating gate; a control gate disposed over the laterally oxidized intervention layer; and a selection unit disposed on the substrate. The selection unit comprises a selection unit insulating layer and a selection unit conductive layer.

Another aspect of the present disclosure provides a method for fabricating a semiconductor device, comprising: providing a substrate; forming a first well region and an isolation structure in the substrate;

forming a memory unit, a control unit, and a selection unit on the substrate; forming a plurality of doped regions in the substrate; performing a lateral oxidation process over the substrate; forming a plurality of memory unit spacers, a memory top conductive layer, a plurality of selection unit spacers, and a selection unit top conductive layer over the substrate; forming a passivation insulating layer on the substrate; and forming a plurality of doped region contacts in the passivation insulating layer.

Although the present disclosure and its advantages have been described in detail, it should be understood that various changes, substitutions, and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods, and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods and steps.

What is claimed is:

1. A semiconductor device, comprising:
a substrate;
a tunnel insulating layer disposed over the substrate;
a floating gate disposed over the tunnel insulating layer;
a laterally oxidized intervention layer disposed over the floating gate, wherein the laterally oxidized intervention layer comprises a sidewall portion and a center portion, and the sidewall portion has an oxygen concentration greater than that of the center portion; and
a control gate disposed over the laterally oxidized intervention layer.

2. The semiconductor device of claim 1, further comprising a plurality of doped regions disposed in the substrate.

3. The semiconductor device of claim 2, further comprising a first well region in the substrate, wherein the plurality of doped regions are disposed in the first well region.

4. The semiconductor device of claim 3, further comprising a plurality of memory unit spacers disposed on the substrate and attached to sidewalls of the tunnel insulating layer.

5. The semiconductor device of claim 4, further comprising a memory top conductive layer disposed over the control gate.

6. The semiconductor device of claim 5, wherein the laterally oxidized intervention layer has a thickness between 10 angstroms and about 350 angstroms.

7. The semiconductor device of claim 6, wherein the tunnel insulating layer has a thickness different from a thickness of the laterally oxidized intervention layer, and the tunnel insulating layer is formed of a material different from the material of the laterally oxidized intervention layer.

8. The semiconductor device of claim 7, further comprising a passivation insulating layer disposed on the substrate, wherein the passivation insulating layer covers the memory top conductive layer and the memory unit spacers.

9. The semiconductor device of claim 8, further comprising a plurality of doped region contacts extending from a top surface of the passivation insulating layer into the doped regions, wherein the doped region contacts are electrically coupled to the doped regions.

10. The semiconductor device of claim 9, wherein the doped region contact comprises a lower portion and an upper portion, wherein the lower portion of the doped region contact extends into the doped region, and the upper portion of the doped region contact is surrounded by the passivation insulating layer.

11. The semiconductor device of claim 10, wherein the lower portion of the doped region contact has a first critical dimension, and the upper portion of the doped region contact has a second critical dimension greater than the first critical dimension.

12. The semiconductor device of claim 11, wherein the first critical dimension gradually decreases at positions of increasing distance from a top surface of the substrate, while the second critical dimension is constant.

13. The semiconductor device of claim 12, wherein a peripheral surface of the lower portion of the doped region contact is discontinuous with a peripheral surface of the upper portion of the doped region contact.

14. The semiconductor device of claim 13, wherein the lower portion of the doped region contact and the upper portion of the doped region contact are integrally formed.

15. The semiconductor device of claim 8, further comprising a plurality of doped region contacts extending from a top surface of the passivation insulating layer to a top surface of the substrate, wherein the doped region contacts are electrically coupled to the doped regions.

16. The semiconductor device of claim 15, wherein the doped region contact comprises a barrier layer and a conductive layer disposed over and surrounded by the barrier layer, wherein the passivation insulating layer surrounds the barrier layer of the doped region contact.

17. The semiconductor device of claim 16, wherein the barrier layer has a first thickness on sidewalls of the conductive layer and a second thickness under a bottom surface of the conductive layer, wherein the first thickness of the barrier layer is less than the second thickness of the barrier layer.
